(19) United States
(12) Patent Application Publication
(10) Pub. No.: US 2025/0299950 A1
(43) Pub. Date: Sep. 25, 2025

(54) SEMICONDUCTOR STRUCTURE AND MANUFACTURING METHOD THEREOF

(71) Applicant: Hon Young Semiconductor Corporation, Hsinchu City (TW)

(72) Inventors: Hung-Hsin YEN, Hsinchu City (TW); Chin-Hung CHEN, Hsinchu City (TW)

(21) Appl. No.: 18/664,324

(22) Filed: May 15, 2024

(30) Foreign Application Priority Data
Mar. 21, 2024 (TW) 113110615

(51) Int. Cl. H01L 21/02; C30B 25/18; C30B 25/20; C30B 29/36; H01L 29/16; H01L 29/34

(52) U.S. Cl. CPC H01L 21/02378; C30B 25/186; C30B 25/20; C30B 29/36; H01L 21/02013; H01L 21/02019; H01L 21/02529; H01L 21/02634; H10D 62/57; H10D 62/8325

(57) ABSTRACT

A semiconductor structure includes a silicon carbide substrate and an epitaxial layer. A top surface of the silicon carbide substrate has a plurality of recesses, a bottommost portion of each of the recesses, has a first inclined surface and a second inclined surface connected with each other, and an angle between the first inclined surface and the second inclined surface is 88 degrees to 92 degrees. The epitaxial layer is disposed on the top surface of the silicon carbide substrate.

### CROSS-REFERENCE TO RELATED APPLICATION

This application claims priority to Taiwan Application Serial Number 113110615, filed Mar. 21, 2024, which is herein incorporated by reference.

### BACKGROUND

### Field of Disclosure

The present disclosure relates to a semiconductor structure and a manufacturing method thereof.

### Description of Related Art

Silicon carbide (SiC) is a special semiconductor material with characteristics such as wide bandgap, high critical breakdown electric field, high thermal conductivity, and high saturation of carrier's drift velocity, making it suitable for manufacturing semiconductor devices for high temperature, high voltage, high power, and radiation resistance applications. Although silicon carbide material has many advantages, it often contains a large number of defects, such as basal plane dislocations (BPD). These defects can further extend from the substrate to the epitaxial layer, leading to increased reverse leakage current or reduced breakdown voltage of semiconductor devices, resulting in reduced reliability of semiconductor devices. Compared to BPD, the impact of threading edge dislocations (TED) on the performance of semiconductor devices is smaller. Therefore, how to increase the proportion of BPD converted to TED during silicon carbide epitaxial growth and prevent BPD in the substrate from extending into the epitaxial layer is essential for improving the performance of semiconductor devices.

### SUMMARY

According to some embodiments of the present disclosure, a semiconductor structure includes a silicon carbide substrate and an epitaxial layer. A top surface of the silicon carbide substrate has a plurality of recesses, a bottommost portion of each of the recesses, has a first inclined surface and a second inclined surface connected with each other, and an angle between the first inclined surface and the second inclined surface is 88 degrees to 92 degrees. The epitaxial layer is disposed on the top surface of the silicon carbide substrate.

According to some embodiments of the present disclosure, a method for manufacturing a semiconductor structure includes: performing an etching process on a top surface of a silicon carbide substrate using an alkaline etching solution, in which the alkaline etching solution includes at least one alkaline substance with a hydroxyl group; after the etching process, performing a grinding process on the top surface of the silicon carbide substrate using a grinding solution including hydrogen peroxide and a plurality of silicon dioxide particles; and performing an epitaxial process on the top surface of the silicon carbide substrate to form an epitaxial layer.

According to some embodiments of the present disclosure, a method for manufacturing a semiconductor structure includes performing an etching process on a top surface of a silicon carbide substrate to form a plurality of etching pits, in which an average maximum width of the etching pits is 30 μm to 50 μm; after the etching process, performing a grinding process on the top surface of the silicon carbide substrate to reduce the average maximum width of the etching pits to 5 μm to 35 μm; and performing an epitaxial process on the top surface of the silicon carbide substrate to form an epitaxial layer.

According to the aforementioned embodiments of the present disclosure, through pretreating the silicon carbide substrate before epitaxial growth, multiple recesses are formed on the top surface of the silicon carbide substrate, thereby altering the surface properties of the silicon carbide substrate. This process can enhance the conversion efficiency of basal plane dislocations (BPDs) into threading edge dislocations (TEDs), thereby improving the epitaxial quality.

### BRIEF DESCRIPTION OF THE DRAWINGS

The disclosure can be more fully understood by reading the following detailed description of the embodiments, with reference made to the accompanying drawings as follows:

FIG. 1 is a schematic side view of a semiconductor structure according to some embodiments of the present disclosure;

FIG. 2 is a schematic side view of a semiconductor structure of Comparative Example; and

FIG. 3 is a flowchart of a manufacturing method of a semiconductor structure according to some embodiments of the present disclosure.

### DETAILED DESCRIPTION

The present disclosure relates to a method for improving the reliability of semiconductor structures. Specifically, by pre-treating a silicon carbide substrate before epitaxial growth of silicon carbide, this disclosure alters the surface properties of the silicon carbide substrate, enhances the conversion efficiency of basal plane dislocations (BPD) to threading edge dislocations (TED), thereby reducing the probability of forming killer defects and improving epitaxial quality. Consequently, the semiconductor structure disclosed herein can meet the performance and reliability requirements of high-voltage and high-current electronic devices.

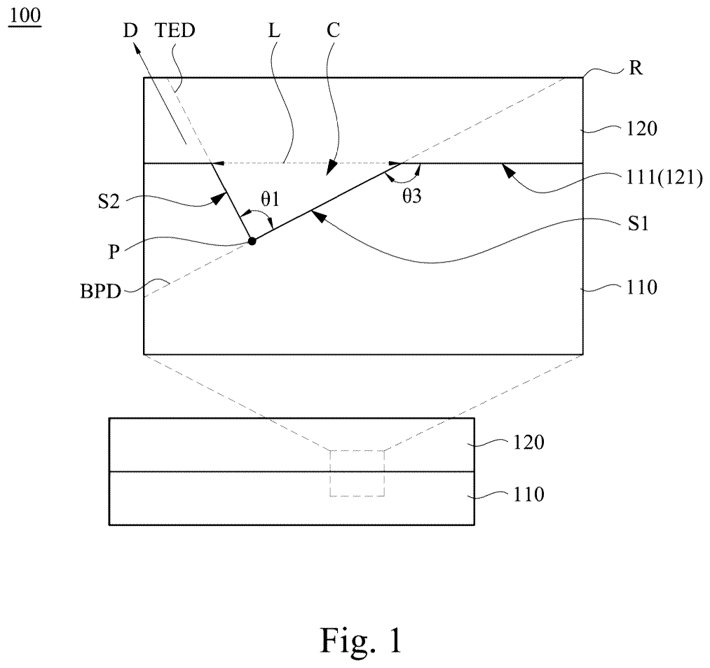

Reference is made to FIG. 1, which is a schematic side view of a semiconductor structure 100 according to some embodiments of this disclosure. Specifically, the semiconductor structure 100 of the present disclosure includes a silicon carbide substrate 110 and an epitaxial layer 120, in which the epitaxial layer 120 is disposed on the top surface 111 of the silicon carbide substrate 110, and the top surface 111 of the silicon carbide substrate 110 is a crystal growth surface. It should be understood that the silicon carbide substrate 110 of the present disclosure has a 4H—SiC crystal structure, and homogeneous epitaxy of 4H—SiC is expected.

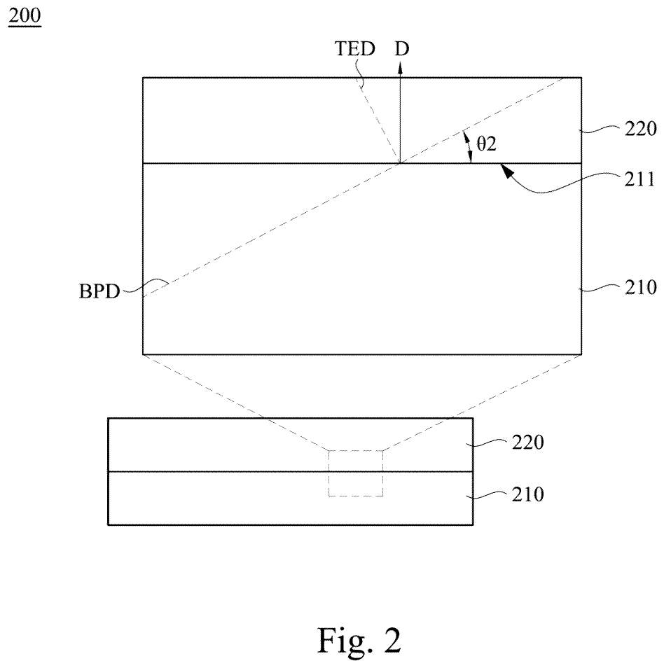

Reference is made to the enlarged region R in FIG. 1. The top surface 111 of the silicon carbide substrate 110 has multiple recesses C. The bottommost portion of each recess C has a first inclined surface S1 and a second inclined surface S2 connected with each other, meaning the lowest point P of each recess C lies on the intersection of the first inclined surface S1 and the second inclined surface S2. Furthermore, the angle θ1 between the first inclined surface S1 and the second inclined surface S2 is 88 degrees to 92 degrees. For example, θ1 can be 88 degrees, 89 degrees, 90 degrees, 91 degrees, or 92 degrees. With this design, during subsequent epitaxial growth from the silicon carbide substrate 110 upwards to form the epitaxial layer 120, the conversion efficiency of BPD to TED can be increased, thereby improving epitaxial quality. In some preferred embodiments, θ1 is 90 degrees. The reasons for this will be explained by comparing FIG. 1 with FIG. 2. It should be noted that the Burgers vector direction of BPD (denoted as “BPD” in the figure) is perpendicular to the Burgers vector direction of TED (denoted as “TED” in the figure).

Reference is made to FIG. 2, which is a schematic side view of a semiconductor structure 200 of Comparative Example. The semiconductor structure 200 includes a silicon carbide substrate 210 and an epitaxial layer 220 disposed on a top surface 211 of the silicon carbide substrate 210. When a silicon carbide substrate 210 without any recesses C is used, the angle θ2 between the top surface 211 of the silicon carbide substrate 210 and the Burgers vector direction of BPD is 4 degrees, and the direction D of epitaxial growth is perpendicular to the top surface 211 of the silicon carbide substrate 210. In this case, according to equations (1) and (2) below, since the elastic energy per unit length of dislocation line (EBPD) for basal plane dislocations (BPD) is approximately equal to the elastic energy per unit length of dislocation line (ETED) for threading edge dislocations (TED), the elastic energy per unit growth length (WBPD) for BPD is greater than the elastic energy per unit growth length (WTED) for TED. Therefore, most of the BPDs will transform into TEDs during the epitaxial growth process.

$${W}_{BPD} = {E}_{BPD} / cos 86 ° \qquad Equation ( 1 )$$

$${W}_{TED} = {E}_{TED} / cos 4 ° \qquad Equation ( 2 )$$

$$\to {W}_{BPD} > {W}_{TED} ( {E}_{BPD} \approx {E}_{TED} )$$

Returning to FIG. 1. Due to the multiple recesses C on the top surface 111 of the silicon carbide substrate 110 disclosed herein, in which the bottommost portion of each recess C has an angle θ1 of 88 degrees to 92 degrees, the direction D of epitaxial growth is perpendicular to the first inclined surface S1 of the silicon carbide substrate 110. In this case, according to equations (3) and (4) below, the difference between the elastic energy per unit growth length for BPD (WBPD) and the elastic energy per unit growth length for TED (WTED) increases (compared to the situation in FIG. 2), allowing more BPD to transform into TED during epitaxial growth. Here, equations (3) and (4) are calculated using a 90-degree angle θ1 as an example.

$${W}_{BPD} = {E}_{BPD} / cos 90 ° \qquad Equation ( 3 )$$

$${W}_{TED} = {E}_{TED} / cos 0 ° \qquad Equation ( 4 )$$

$$\to {W}_{BPD} ≫ {W}_{TED} ( {E}_{BPD} \approx {E}_{TED} )$$

In some embodiments, each of the first inclined surface S1 and the second inclined surface S2 extends straight to the top surface 111, and the angle θ3 between the top surface 111 and the first inclined surface S1 is 174 degrees to 178 degrees. For example, θ3 can be 175 degrees, 176 degrees, or 177 degrees. With this design, the entire first inclined surface S1 can have a high BPD conversion efficiency, thereby improving epitaxial quality. In some preferred embodiments, θ3 is 176 degrees.

In some embodiments, the average maximum width L of the recesses C can be 5 μm to 35 μm. For example, the average maximum width L of the recesses C can be 10 μm, 15 μm, 20 μm, 25 μm, or 30 μm. Since the average maximum width L of the recesses C is small, from the perspective of crystal growth, the recesses C do not affect the overall flatness of the top surface 111 of the silicon carbide substrate 110, thereby reducing the probability of large defects (e.g., triangular defects, carrot defects) due to surface roughness. On the other hand, although the recesses C are small in size, they still have a certain degree of dimension, which is advantageous for constructing an appropriate angle θ1, thereby increasing the BPD conversion efficiency. It should be understood that the “maximum width L of the recesses C” herein refers to “the maximum length measured along a direction parallel to the top surface 111 of the recesses C,” and the “average maximum width L of the recesses C” is obtained by averaging the maximum widths L of 15000 recesses C.

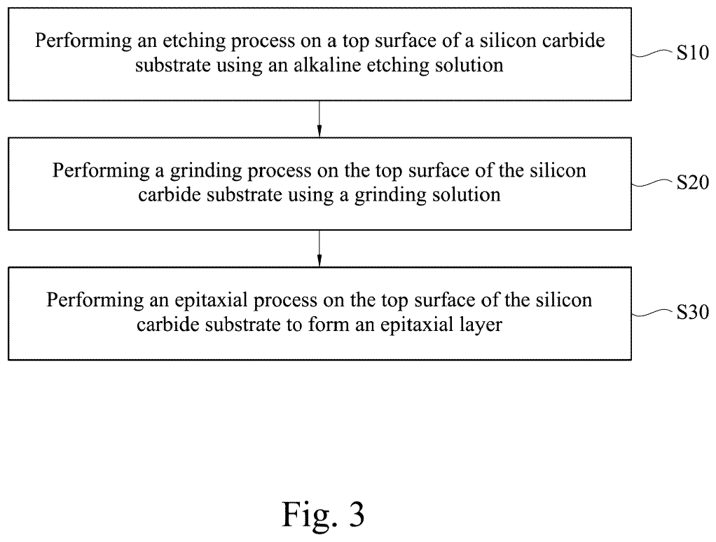

In the following descriptions, the manufacturing method of the semiconductor structure 100 disclosed herein will be described through FIG. 1 and FIG. 3, in which is a flowchart of a manufacturing method of a semiconductor structure 100 according to some embodiments of the present disclosure. The manufacturing method of the semiconductor structure 100 includes steps S10 to S30, and steps S10 to S30 are performed sequentially.

In step S10, an etching process is performed on the top surface 111 of the silicon carbide substrate 110 using an alkaline etchant (etching solution), in which the alkaline etchant contains at least one alkaline substance with hydroxyl groups. By etching the top surface 111 of the silicon carbide substrate 110 with a strong base containing hydroxyl groups, multiple etching pits (not shown) with suitable dimensions can be etched on the top surface 111 of the silicon carbide substrate 110. Specifically, the average maximum width of the multiple etching pits formed by the etching process is 30 μm to 50 μm (e.g., 35 μm, 40 μm, or 45 μm). Smaller etching pits can be directly retained and become recesses C, while larger etching pits can be partially leveled during subsequent grinding processes to reduce their size and become recesses C. On the other hand, by using a strong base containing hydroxyl groups for the etching process, the etching pits can also have the appropriate angle θ1 mentioned above, thereby resulting in recesses C with a suitable angle θ1. It should be understood that the “maximum width of the etching pits” herein refers to “the maximum length measured along a direction parallel to the top surface 111 of the etching pits,” and the “average maximum width of the etching pits” is obtained by averaging the maximum widths of 15,000 etching pits.

In some embodiments, the alkaline substance in the alkaline etchant can be potassium hydroxide, sodium hydroxide, tetramethylammonium hydroxide, or combinations thereof. In some preferred embodiment, the alkaline substance can be potassium hydroxide to better control the size and angle θ1 of the etching pits formed. In some embodiments, the alkaline etchant can be an aqueous solution containing the alkaline substance, such as an aqueous solution containing potassium hydroxide. In some embodiments, based on a total weight of the alkaline etching solution, a weight of the alkaline substance in the alkaline etching solution is 80 wt. % to 90 wt. %, this helps control the size and angle θ1 of the etching pits. In other embodiments, the alkaline etchant can be pure molten potassium hydroxide, which has better etching effects for silicon carbide substrates 110 with higher BPD densities.

In some embodiments, the time of the etching process can be 2 minutes to 20 minutes, and the etching process temperature can be 300° C. to 600° C. (e.g., 350° C., 400° C., 450° C., 500° C., 550° C.). By controlling the time of the etching process within 20 minutes, the formation of etching pits with excessively large dimensions can be avoided, thereby reducing the time and amount of grinding solution used in subsequent grinding processes and improving the overall efficiency of the process. In addition, by controlling the temperature within the range of 300° C. to 600° C., appropriate reactivity between the alkaline substance in the alkaline etchant and the silicon carbide substrate 110 can be achieved, which helps control the size and angle θ1 of the etching pits.

After the etching process, in step S20, a grinding process is performed on the top surface 111 of the silicon carbide substrate 100 using a grinding solution including hydrogen peroxide and multiple silicon dioxide particles. Specifically, hydrogen peroxide rapidly heats and oxidizes the top surface 111 of the silicon carbide substrate 100, thereby forming a soft oxide, while the silicon dioxide particles remove the soft oxide, thereby smoothing out the unexpected surface roughness caused by the etching process. This reduces the probability of large defects forming during subsequent epitaxial growth due to the unevenness of the top surface 111 of the silicon carbide substrate 100. Overall, the grinding process reduces the average maximum width of the etching pits to 5 μm to 35 μm (e.g., 10 μm, 15 μm, 20 μm, 25 μm, 30 μm).

In some embodiments, the average diameter of the silicon dioxide particles can be 70 nm to 80 nm (e.g., 71 nm, 72 nm, 73 nm, 74 nm, 75 nm, 76 nm, 77 nm, 78 nm, 79 nm). Designing silicon dioxide particles with appropriate sizes helps improve their dispersion, avoiding silicon dioxide particle aggregation and the formation of scratches on the top surface 111 of the silicon carbide substrate 110. Additionally, silicon dioxide particles with suitable sizes prevent the removal of etching pits with specific angles 81, ensuring the enhancement of the BPD conversion efficiency. In some embodiments, based on a total weight of the grinding solution, a weight of the silicon dioxide particles is 5 wt. % to 25 wt. %. This concentration range improves the dispersion of the silicon dioxide particles, prevents silicon dioxide particle aggregation, and allows the silicon dioxide particles to be properly cooperated with hydrogen peroxide, thereby enhancing the grinding rate and achieving higher grinding quality.

In some embodiments, controlling the grinding depth of the top surface 111 of the silicon carbide substrate 100 can reduce the probability of large defects. Specifically, the grinding depth of the grinding process on the top surface 111 of the silicon carbide substrate 110 can be 0.1 μm to 0.2 μm. For example, the grinding depth can be 0.11 μm, 0.12 μm, 0.13 μm, 0.14 μm, 0.15 μm, 0.16 μm, 0.17 μm, 0.18 μm, or 0.19 μm. If the grinding depth is too large, most of the etching pits may be removed, failing to leave recesses C on the top surface 111 of the silicon carbide substrate 100. If the grinding depth is too small, the surface roughness of the top surface 111 of the silicon carbide substrate 100 may not be removed, increasing the probability of large defects during subsequent epitaxial growth.

Overall, after the grinding process, the remaining etching pits on the top surface 111 of the silicon carbide substrate 100 can form the recesses C disclosed herein, in which the bottommost portion of each of the recesses C has connected first and second inclined surfaces S1 and S2, and the angle θ1 between the first and second inclined surfaces S1 and S2 is 88 degrees to 92 degrees.

Subsequently, in step S30, an epitaxial process is performed on the top surface 111 of the silicon carbide substrate 110 to form an epitaxial layer 120. Specifically, the growth source (e.g., carbon source and silicon source) and dopant source (e.g., nitrogen source) can be continuously introduced under the epitaxial temperature to grow the epitaxial layer 120 on the silicon carbide substrate 100 with recesses C. In some embodiments, the epitaxial temperature can be 1550° C. to 1650° C., the ratio of the molar concentration of carbon to silicon (C/Si Ratio) in the growth source can be 0.9 to 1.3, and the supply concentration of the dopant source can be 1E15 atoms/cm³ to 5E16 atoms/cm³, in which the carbon source may include methane, propane, ethylene, acetylene, or combinations thereof, and the silicon source may include chlorosilane, dichlorosilane, trichlorosilane, tetrachlorosilane, or combinations thereof, and the nitrogen source may include nitrogen gas, ammonia, or combinations thereof.

As depicted in FIG. 1, because the epitaxial growth of silicon carbide starts from recesses C, and the growth direction D is perpendicular to the first inclined surface S1 of the silicon carbide substrate 210, a portion of the epitaxial layer 120 will be located within recesses C and entirely fill the recesses C. In other words, the epitaxial layer 120 and the silicon carbide substrate 110 are closely arranged without any other layers or gaps between them. In other words, the bottom surface 121 of the epitaxial layer 120 conforms to the contours of the top surface 111, the first inclined surface S1, and the second inclined surface S2 of the silicon carbide substrate 110 (i.e., the bottom surface 121 of the epitaxial layer 120 undulates with the contours of the top surface 111, the first inclined surface S1, and the second inclined surface S2 of the silicon carbide substrate 110), and the epitaxial layer 120 is in close (direct) contact with the silicon carbide substrate 110.

On the other hand, by forming multiple recesses C with suitable angles 81 on the top surface 111 of the silicon carbide substrate 110, the probability of BPDs extending into the epitaxial layer 120 from the silicon carbide substrate 110 can be reduced, and the efficiency of BPD conversion to TED can be increased. Specifically, in some embodiments, during the epitaxial process, the conversion rate from Basal Plane Dislocations (BPDs) to Threading Edge Dislocations (TEDs) in the epitaxial layer 120 is greater than 99.98%. Additionally, in some embodiments, after the epitaxial process, the density of Basal Plane Dislocations (BPDs) in the silicon carbide substrate 110 is 5000 to 30000 times of the density of Basal Plane Dislocations (BPDs) in the epitaxial layer 120.

What is claimed is:

1. A semiconductor structure, comprising:
a silicon carbide substrate, wherein a top surface of the silicon carbide substrate has a plurality of recesses, a bottommost portion of each of the recesses has a first inclined surface and a second inclined surface connected with each other, and an angle between the first inclined surface and the second inclined surface is 88 degrees to 92 degrees; and
an epitaxial layer disposed on the top surface of the silicon carbide substrate.

2. The semiconductor structure according to claim 1, wherein the first inclined surface and the second inclined surface extend straight to the top surface, and an angle between the top surface and the first inclined surface is 174 degrees to 178 degrees.

3. The semiconductor structure according to claim 1, wherein an average maximum width of the recesses is 5 μm to 35 μm.

4. The semiconductor structure according to claim 1, wherein a basal plane dislocation density of the silicon carbide substrate is 5000 times to 30000 times of a basal plane dislocation density of the epitaxial layer.

5. The semiconductor structure according to claim 1, wherein a portion of the epitaxial layer entirely fills the recesses.

6. A method for manufacturing a semiconductor structure, comprising:
performing an etching process on a top surface of a silicon carbide substrate using an alkaline etching solution, wherein the alkaline etching solution comprises at least one alkaline substance with a hydroxyl group;
after the etching process, performing a grinding process on the top surface of the silicon carbide substrate using a grinding solution comprising hydrogen peroxide and a plurality of silicon dioxide particles; and
performing an epitaxial process on the top surface of the silicon carbide substrate to form an epitaxial layer.

7. The method for manufacturing the semiconductor structure according to claim 6, wherein a time of the etching process is 2 minutes to 20 minutes, and a temperature of the etching process is 300° C. to 600° C.

8. The method for manufacturing the semiconductor structure according to claim 6, wherein the alkaline substance is potassium hydroxide, sodium hydroxide, tetramethylammonium hydroxide, or combinations thereof.

9. The method for manufacturing the semiconductor structure according to claim 6, wherein the alkaline substance is potassium hydroxide.

10. The method for manufacturing the semiconductor structure according to claim 6, wherein based on a total weight of the alkaline etching solution, a weight of the alkaline substance in the alkaline etching solution is 80 wt. % to 90 wt. %.

11. The method for manufacturing the semiconductor structure according to claim 6, wherein an average particle diameter of the silicon dioxide particles is 70 nm to 80 nm.

12. The method for manufacturing the semiconductor structure according to claim 6, wherein based on a total weight of the grinding solution, a weight of the silicon dioxide particles is 5 wt. % to 25 wt. %.

13. The method for manufacturing the semiconductor structure according to claim 6, wherein a grinding depth of the grinding process on the top surface of the silicon carbide substrate is 0.1 μm to 0.2 μm.

14. A method for manufacturing a semiconductor structure, comprising:
performing an etching process on a top surface of a silicon carbide substrate to form a plurality of etching pits, wherein an average maximum width of the etching pits is 30 μm to 50 μm;
after the etching process, performing a grinding process on the top surface of the silicon carbide substrate to reduce the average maximum width of the etching pits to 5 μm to 35 μm; and
performing an epitaxial process on the top surface of the silicon carbide substrate to form an epitaxial layer.

15. The method for manufacturing the semiconductor structure according to claim 14, wherein a basal plane dislocation density of the silicon carbide substrate is 5000 times to 30000 times of a basal plane dislocation density of the epitaxial layer.

16. The method for manufacturing the semiconductor structure according to claim 14, wherein during the epitaxial process, a conversion rate from a basal plane dislocation to a threading edge dislocation in the epitaxial layer is greater than 99.98%.

17. The method for manufacturing the semiconductor structure according to claim 14, wherein after the grinding process, a bottommost portion of each of the etching pits has a first inclined surface and a second inclined surface connected with each other, and an angle between the first inclined surface and the second inclined surface is 88 degrees to 92 degrees.

18. The method for manufacturing the semiconductor structure according to claim 14, wherein the grinding process on the top surface of the silicon carbide substrate is performed using a grinding solution comprising a plurality of silicon dioxide particles, and an average particle diameter of the silicon dioxide particles is 70 nm to 80 nm.

19. The method for manufacturing the semiconductor structure according to claim 18, wherein based on a total weight of the grinding solution, a weight of the silicon dioxide particles is 5 wt. % to 25 wt. %.

20. The method for manufacturing the semiconductor structure according to claim 14, wherein a grinding depth of the grinding process on the top surface of the silicon carbide substrate is 0.1 μm to 0.2 μm.
